(19) United States
(12) Patent Application Publication
(10) Pub. No.: US 2005/0001673 A1
(43) Pub. Date: Jan. 6, 2005

(54) Direct digital frequency modulation / phase modulation decoder

(76) Inventor: Zvi Regev, West Hills, CA (US)

Correspondence Address: ZVI REGEV, 24217 HIGHLANDER RD., WEST HILLS, CA, 91307, US

(21) Appl. No.: 10/696,408

(22) Filed: Oct. 28, 2003

Related U.S. Application Data
(60) Provisional application No. 60/421,859, filed on Oct. 29, 2002.

(51) Int. Cl. H03D 3/00

(52) U.S. Cl. 329/315

(57) ABSTRACT

The present invention provides a method and circuits for digital demodulation of FM and PM modulated signals. In both cases a direct digital phase digitizer is used to obtain the instantaneous phases of the input signal. Digital signal processing circuits comprising only of registers, adders and subtractors, is used to extract the modulating signals from the instantaneous phase information.

### FIELD OF THE INVENTION

The present invention relates generally to signal demodulators, and particularly to decoders of Phase and Frequency modulations.

### BACKGROUND OF THE INVENTION

Phase and frequency modulations are widely used in communication, and the decoding of such modulated signals has been the subject of many articles and inventions.

In phase modulation, the instantaneous phase deviation of the modulated signal from its unmodulated value is proportional to the instantaneous amplitude of the modulating signal. For a general modulating signal vₘ(t), the instantaneous phase deviation is, Θ(t)=k_{Θ}vₘ(t), wherein k_{Θ} is the phase deviation constant in radians per volts. For Vₘ defined as the maximum value of |vₘ(t)|, it is convenient to define a “normalized” v(t)=[vₘ(t)]/Vₘ, and in this notation, Θ(t)=k_{Θ}Vₘv(t), and the maximum phase shift, k_{Θ}Vₘ=ΔΘ=mₚ is called the modulation index for phase modulation.

In terms of mₚ the phase modulated signal is written as Fₚₘ(t)=A cos[ω_{c}t+mₚv(t)], and the instantaneous phase deviation is Θ(t)=mₚv(t), radians.

The instantaneous frequency of the modulated signal is

$$ω ( t ) = {ω}_{c} + \frac{ⅆ Θ ( t )}{ⅆ t} = {ω}_{c} + {m}_{p} \frac{ⅆ v ( t )}{ⅆ t} .$$

Frequency modulation results when the deviation δω of the instantaneous frequency ω(t) from the carrier frequency ω_{c} is directly proportional to the instantaneous amplitude of the modulating voltage.

Since

$$ω ( t ) = \frac{ⅆ ϕ}{ⅆ t} = {ω}_{r} + \frac{ⅆ Θ ( t )}{ⅆ t}$$

the frequency deviation δω of ω(t) from ω_{c} is given by

$$δω ( t ) = ω ( t ) - {ω}_{c} = \frac{ⅆ Θ ( t )}{ⅆ t} .$$

In frequency modulation δω(t) is proportional to the modulating voltage vₘ(t), as δω(t)=kₘvₘ(t), in which kₘ is the sensitivity of the modulator in rad/s/V. Since Θ(t), and δω(t) are related, as shown above, then Θ(t)=∫₀¹kₘvₘ(t)dt+Θ(0), and assuming Θ(0)=0,

And F_{FM}=A cos└ωω_{c}t+kₘ∫₀¹vₘ(t)dt┘.

Demodulators of Phase and Frequency modulated signals, are used to extract the modulating signal vₘ(t) from the modulated signal. Such demodulators typically comprise of tuned circuits, or phase locked loops, in which a phase or frequency deviation causes a change in the output voltage, which is directly related to the magnitude of the phase or frequency deviation.

A simple FM demodulator is based on an LC tank resonator circuit. In resonance the amplitude versus the frequency response of the tuned circuit has the shape of a bell, as shown in FIG. 1. The LC tank is tuned to resonate, such that the center frequency (carrier frequency) of the FM modulated signal, and therefore any change in the signal frequency causes a change in the voltage on the resonator.

FIG. 2, shows the most commonly used FM demodulator. To analyze this circuit, consider the voltage relationship in the coupled circuit L1C1-L2C2, in FIG. 2, and FIG. 3. If the impedance coupled into the primary circuit is negligible in comparison with the primary self impedance, then the primary current I₁ will be

$${I}_{1} = \frac{{V}_{1}}{j ω {L}_{1}}$$

The voltage induced in the secondary by I₁ is jωMI₁; at the secondary resonance frequency ω_{c} the secondary current will be:

$${I}_{2} = \frac{j {ω}_{c} {MI}_{1}}{{R}_{2}} = \frac{M}{{L}_{1}} \frac{{V}_{1}}{{R}_{2}}$$

The voltage across the capacitor is: 2V₂=jω_{c}C₂I₂, and therefore

$${V}_{2} = \frac{j {ω}_{c} {C}_{2} M}{2 {L}_{1} {R}_{2}} {V}_{1}$$

At resonance V₂ leads V₁ by 90°. At frequency ω slightly different from ω_{c},

$$\begin{matrix}{V}_{2} = \frac{j ω {C}_{2} M}{2 {L}_{1} {R}_{2}} \times \frac{{V}_{1}}{1 + ( \frac{1}{{R}_{2}} ) [ j ω {L}_{2} + ( 1 / j ω {C}_{2} ) ]} \approx \\ \approx \frac{j ω {C}_{2} {MV}_{1}}{2 {L}_{1} {R}_{2}} \times \{ 1 - \frac{1}{{R}_{2}} [ j ω {L}_{2} + \frac{1}{j {ωC}_{2}} ] \} \\ □\end{matrix}$$

and the phase angle between V₁ and V₂ is given by:

$$Arg ( \frac{{V}_{2}}{{V}_{1}} ) = Arg ( j + \frac{Δω {L}_{2}}{{R}_{2}} - \frac{1}{j ω {C}_{2} {R}_{2}} ) = {cot}^{- 1} ( \frac{ω {L}_{2}}{{R}_{c}} - \frac{1}{ω {C}_{2} {R}_{2}} )$$

Then, if ω=ω_{c}+Δω, the phase angle formula is reduced to

$$Arg ( \frac{{V}_{2}}{{V}_{1}} ) = {cot}^{- 1} ( \frac{Δω {L}_{2}}{{R}_{2}} ) = {{cot}^{- 1} ( \frac{Δω Q}{{ω}_{c}} )}^{wherein} Q = \frac{ω {L}_{2}}{{R}_{2}}$$

which is the Q of the secondary resonant circuit.

For Δω>0, if ω>ω_{c} then the angle is <90°, and if ω<ω_{c} then the angle is >90°, as shown in FIG. 4.

Referring to FIG. 2, assuming that Cₒ and C_{c} are RF shorts, and that RFC is an RF open, the point “A” in FIG. 2, may be considered RF ground, and the RF voltage Vₐ′ applied to the top diode, and the RₒCₒ network is Vₐ′=V₁+V₂. The RF voltage V_{b}′ applied to the bottom diode is V_{b}′=V₁−V₂. The phase relationship between V₁ and V₂ is shown in FIG. 4.

FIG. 5, illustrates the variation of Vₐ′, and V_{b}′ as a function of variations in frequency. The basic relationships are:
Vₐ′=V_{b}′when ω=ω_{c},
   |Vₐ′|<|V_{b}′| when ω<ω_{c},
Vₐ′/>|V_{b}′| when ω>ω_{c}.

The demodulated output from the FM demodulator is V_{d}=|Vₐ′|−|V_{b}′|.

Since the phase deviation is the derivative of the frequency modulation, the phase demodulation is obtained by differentiating the frequency demodulator output.

An alternative method of FM demodulation, uses Phase Locked Loops (PLL), as the means to track frequency and phase deviations, and extract the modulating signal.

Referring to FIG. 6, showing a typical phase locked loop, comprised of a phase/frequency detector (61), a loop filter (62), and a voltage controlled oscillator (63). The control mechanism of the loop tries to maintain the loop in the locked state, wherein the signal at the output of the VCO (65) matches the phase and frequency of the reference input (66). As the reference input (66), which is the modulated signal, changes its phase or frequency, the loop follows those changes in order to stay locked. The voltage output of the loop filter (64) is directly proportional to the modulating signal.

In this invention, some new, completely digital, decoders for phase and frequency modulated signals are described. These decoders do not contain any tuned circuits, nor do they employ any phase locked loops. These decoders are inherently wideband, and the bandwidth of their operation is determined mainly by the frequency of the clock signal used.

This invention uses a direct phase sampler (DPS) to provide numerical information identifying the instantaneous phase of the input signal. FIG. 7, shows a block diagram of a direct phase sampler. The DPS receives the modulated RF signal at its input, and on each clock transition it produces a digital number, indicating the instantaneous phase of the input signal at the time of the clock transition. Such phase samplers have been described before in other patens, and is not the subject of this invention.

Referring to FIG. 8, which shows a block diagram of an embodiment of a PM demodulator. The output of the DPS (100) is applied to a differencing circuit (10), which subtracts the phase of the input signal at the time of the last clock transition, from the phase of the input signal at the time of the previous clock transition, thus providing the phase difference between any two clocks. The output of the differencing circuit is applied both to a “p” deep running averager (20), and to the “A” input of a subtractor (30). The averager calculates the average of phase differences over the last consecutive “p” clock periods. The requirement on the averager length is that if t_{c} is the sampling clock period, and tₘ₍ₘₐₓ₎ is the period of the lowest frequency in the PM modulating bandwidth, then

$$p > 10 \frac{{t}_{m ( max )}}{{t}_{c}}$$

The subtractor (30), which follows the averager (20), subtracts the average phase difference calculated by the averager, from the instantaneous phase difference calculated by the differencing circuit. The resulting output is the variation in phase difference from clock transition to clock transition. A sine lookup table (40), which follows the subtractor (30), converts the phase variations information generated by the subtractor (30), into an amplitude voltage output (45), which is essentially the demodulation of the PM modulated input signal.

FIG. 10, shows a block diagram of an FM demodulator. This demodulator is very similar to the PM demodulator, except that the output of the differencing circuit (10) is not applied directly to the “A” input of the subtractor (30), but instead is connected to a “q” deep running averager (50), who's output connects to the “A” input of the subtractor (30). The requirements for the size of “q” depend on the application. In general, “q” is much smaller than “p”. However, the size of “q” effects the decoder sensitivity, and its fidelity or linearity. The smaller “q” is, the higher is the demodulator's sensitivity, but the lower is its fidelity.

### DESCRIPTION OF THE DRAWINGS

FIG. 1, shows the amplitude versus frequency response of an LC tank resonator circuit.

FIG. 2, shows the schematic of a typical “analog” frequency discriminator.

FIG. 3, shows a circuit to illustrate the phase relationship in the discriminator. The resistors represent the internal resistance of the inductors.

FIG. 4, shows the phase relationship in the discriminator.

FIG. 5 shows the voltages on the diodes in the discriminator.

FIG. 6, shows a Phase Locked Loop FM/PM discriminator.

FIG. 7, shows a block diagram of direct digital phase sampler.

FIG. 8, shows a block diagram of a direct digital PM demodulator.

FIG. 9, shows an embodiment of a PM demodulator.

FIG. 10, shows a block diagram of an FM demodulator.

FIG. 11, shows an embodiment of an FM demodulator.

FIG. 12, shows an embodiment of a receiver comprising a direct digital demodulator.

FIG. 13, shows the waveforms involved in binary to Grey code conversion.

FIG. 14, shows an embodiment of a phase to amplitude converter.

FIG. 15, shows waveforms involved with phase to amplitude conversion.

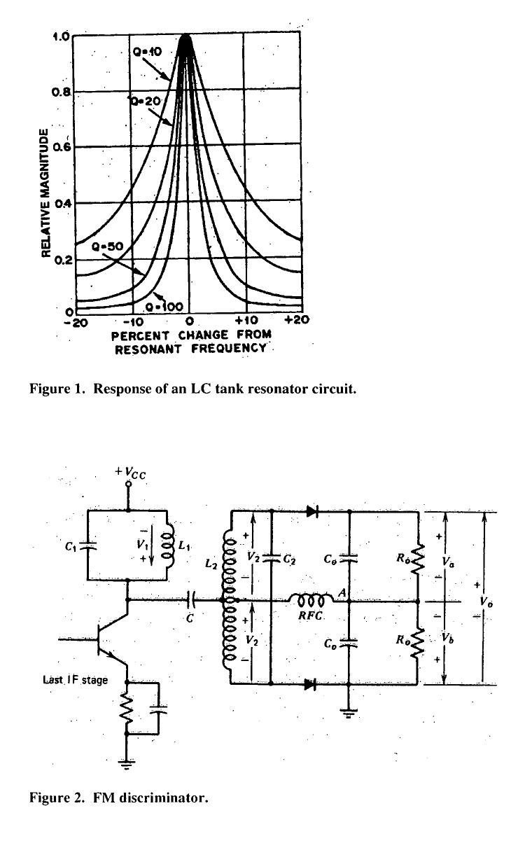

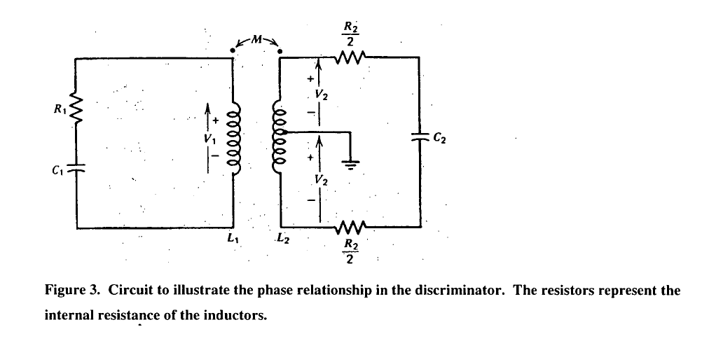

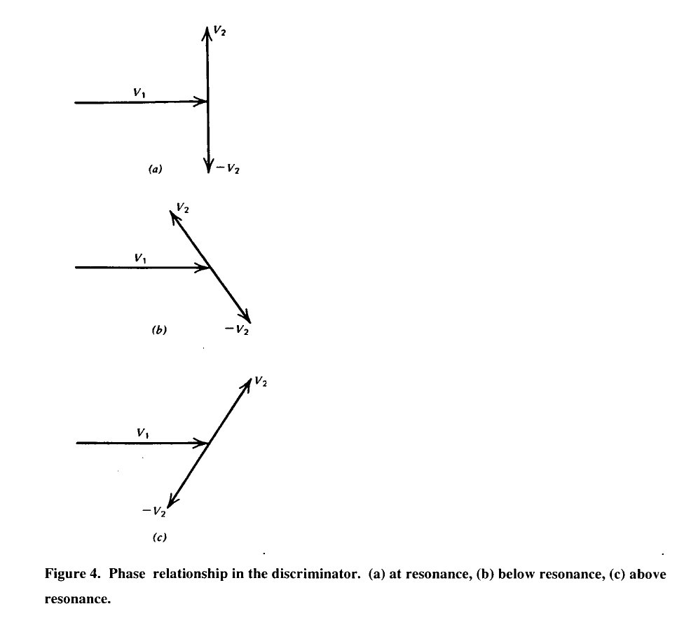

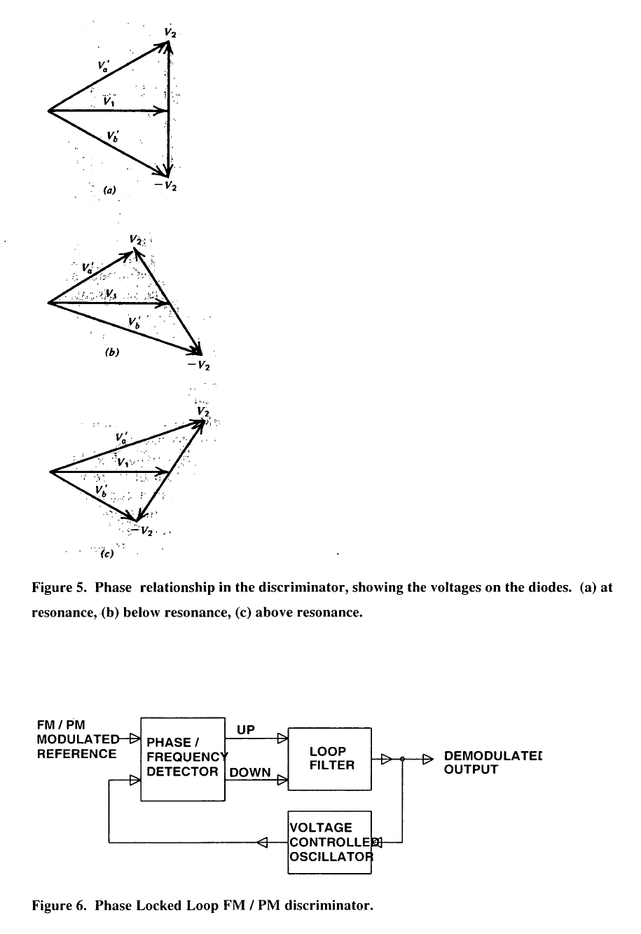

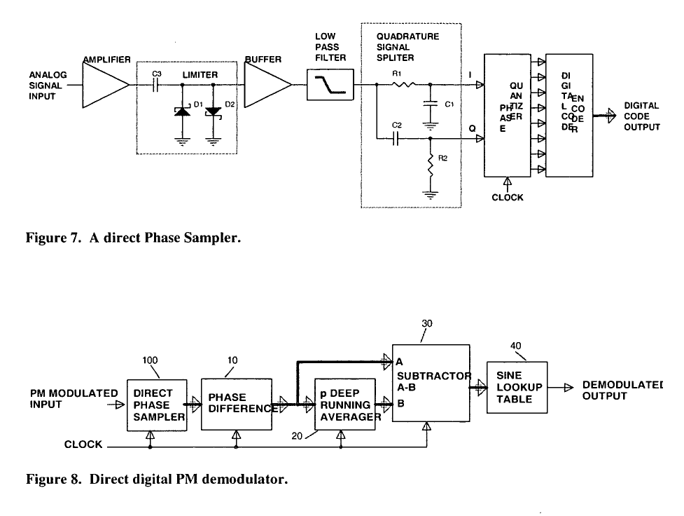

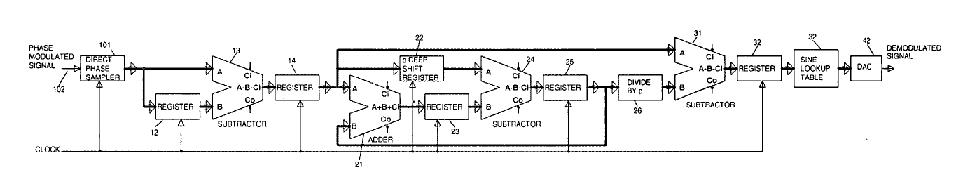

### DESCRIPTION OF THE INVENTION

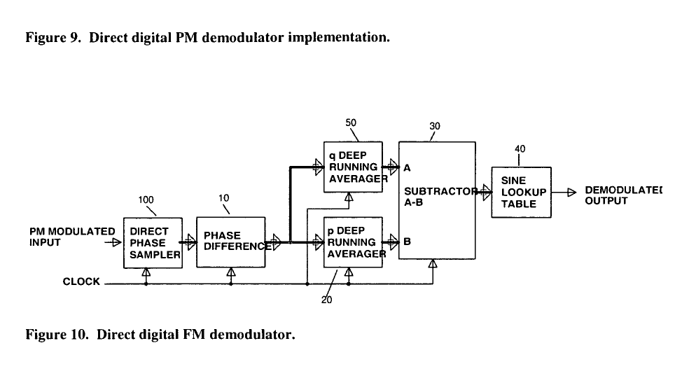

FIG. 9, shows the details of an embodiment of a PM demodulator. The register (12), the subtractor (13), and the register (14), comprise the phase differencing circuit (10). The output of the direct digital phase sampler (101) Θₖ(t) is applied simultaneously to the input of the register (12), and the “A” input of the subtractor (13). The output of the register (13) lags behind the input to that register by one clock period, and thus the input “B” to the subtractor (13) Θₖ₋₁(t) lags one clock period behind the input “A” to the subtractor (13) Θₖ(t). As a result, the output of the subtractor (13), which is the difference between inputs “A” and “B” ΔΘₖ=Θₖ(t)−Θₖ₋₁(t), is actually the change in the phase of the input signal (102), over one clock period, which is the instantaneous frequency of the input signal (102).

The adder (21), the “p” deep shift register (22), the register (23), the subtractor (24), and the register (25), comprise the averager (20). Assuming that initially all registers and shift registers outputs are “0”. The output of the shift register (22) will remain “0” for at least “p” clock cycles, as any non “0” data at the input to the shift register (22) propagates through the shift register in “p” clock periods. The adder (21) adds new data ΔΘₖ coming from the differencing circuit (10) [register (14)], with data Φₖ coming out of the subtractor (24) via the register (25). While the output of the shift register (22) ΔΘₖ₋ₚ is “0” for “p” clock cycles, the output of the subtractor (24) Φₖ=Λₖ−ΔΘₖ₋ₚ is the same as the data at its “B” input Λₖ. As a result, for the first “p” clock cycles, the adder (21) accumulates all the phase differences generated by the subtractor (13) Λₖ₊₁=Φₖ+ΛΘₖ=Λₖ−ΔΘₖ₋ₚ+ΔΘₖ. The divider (26), which follows the register (25) divides the output from the subtractor Φₖ by p, to yield the running average

$$Δ {Θ}_{ACG} = \frac{Σ ( Δ {Θ}_{k} - Δ {Θ}_{k - p} )}{p} .$$

If p is selected p such that p=2″, then the division can be accomplished by simply discarding the n least significant bits at the output of the averager. The output of the averager is the average phase difference for any clock period. Dividing the average phase difference by the clock period yields the average, or center frequency of the input signal

$${F}_{c} = \frac{Δ {Θ}_{AVG}}{{t}_{c}} .$$

The output of the averager (20) ΔΘ_{AVG} is subtracted by the subtractor (31) from the instantaneous phase difference ΔΘₖ to yield the phase deviation θₖ=ΔΘ_{AVG}−ΔΘₖ.

A sine lookup table (41) followed by a digital to analog converter (42), is a convenient way to convert phase information to amplitude information for the demodulator output.

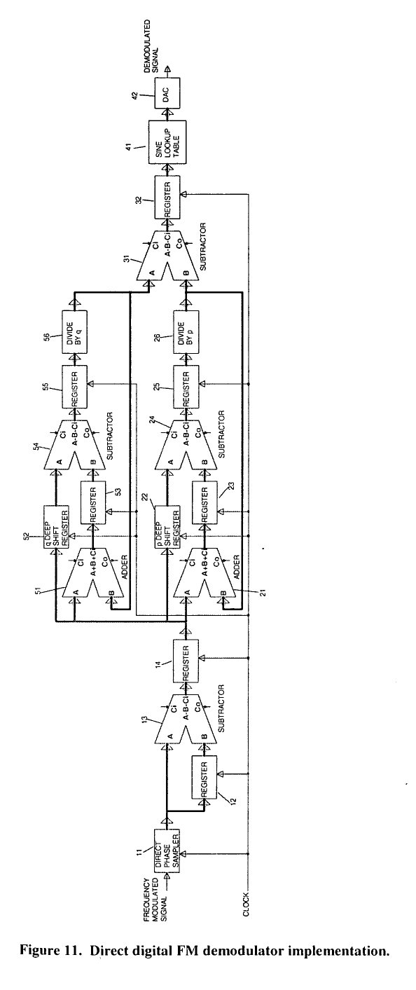

FIG. 11, shows an embodiment of an FM demodulator. This demodulator is very similar to the PM demodulator. It uses the same phase sampler (101), the same differencing circuit (10), the same averager (20), the same subtractor (30) and the same sine lookup table (40). The only difference is that the input “A” of the subtractor (31) is not connected to ΔΘₖ, the output of the differencing circuit (10), but instead, an averager (50), which is comprised of the subtractor (51), q deep shift register (52), register (53), subtractor (54), register (55), and divider (56). The operation of this averager (50), is similar to the operation of the averager (20), with the only difference in the length of the shift register which is q<<p.

In the FM demodulator, the averager (50), having a shift register much shorter than that of the other averager (20), produces the instantaneous deviated frequency

$${F}_{d} = \frac{Δ {Ξ}_{AVG}}{{t}_{c}} ,$$

wherein ΔΞ_{AVG} is the average phase difference per clock period output of the averager (50). The subtractor (31) subtracts the instantaneous deviated frequency from the center frequency, resulting in the frequency deviation ΔF=F_{d}−F_{c}. The sine lookup table (40) converts the phase information into amplitude information, to complete the demodulation process.

An alternative method and circuit for converting phase information into voltage amplitude is shown in FIGS. 13, 14, and 15.

In digital presentation of numbers the bits are assigned values which are power of 2 wherein the least significant bit is assigned the value of 2⁰, the next bit is 2¹, etc. In binary code presentation the order of values in 4 bits is: 0, 1, 2, 3, 4, 5, 6, 7, 8, 9, 10, 11, 12, 13, 14, 15. In a Grey code on the other hand, the order of values is: 0, 1, 3, 2, 6, 7, 5, 4, 12, 13, 15, 14, 10, 11, 9, 8. When these values are presented in 4 bits waveforms, the resulting Grey code waveforms are symmetrical, unlike the binary code, which is non-symmetrical. This symmetry feature of Grey code waveforms enables their use in phase to amplitude conversion.

Obtaining Grey code out of binary code is a straight forward process of EXORing pairs of bits in the form Gₙ=Bₙ⊕Bₙ₊₁. The most significant bit (MSB) in the Grey code is the same as the MSB in binary code, as shown in FIG. 13.

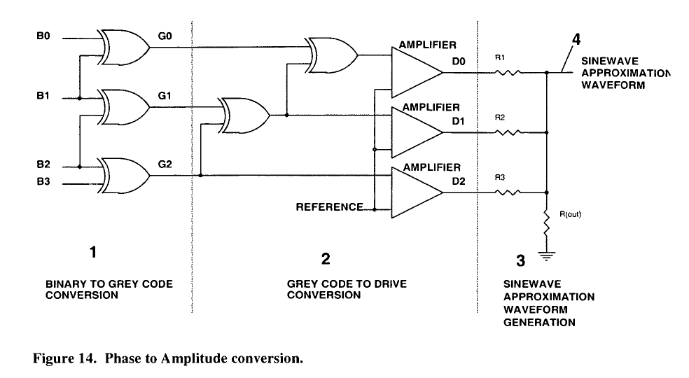

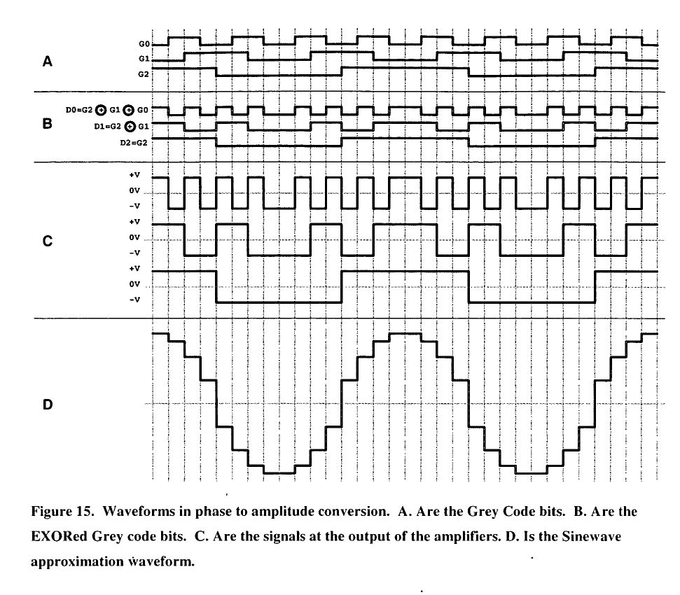

FIG. 14, shows an embodiment of a phase to amplitude converter. Following the conversion of binary to Grey code (1), the Grey code bits are further EXORed (2) and applied to amplifiers with output spanning between a positive supply rail (+V) to a negative supply rail (−V). The resulting voltage waveforms are applied to a resistive network (3). In the resistive network, currents are summed together on the output resistor (R(out)) to generate a sinewave approximation waveform output (4). FIG. 15, shows the waveforms in converting phase information presented in Grey code into a sinewave approximation waveform.

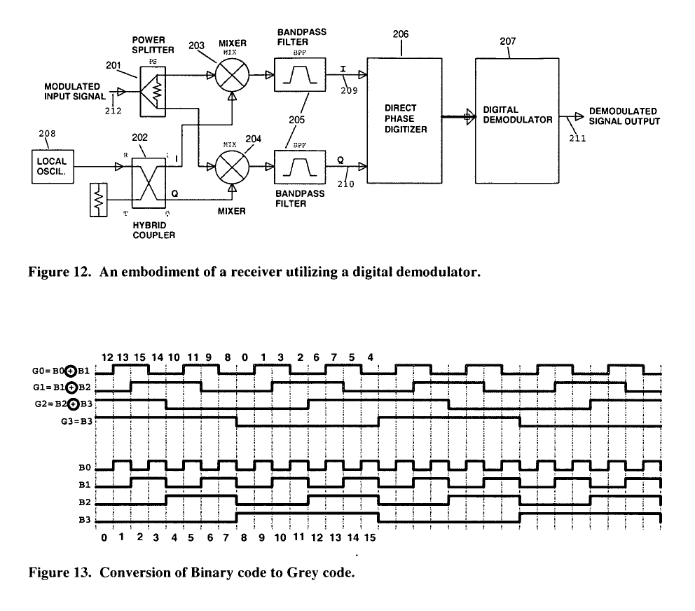

FIG. 12, shows an embodiment of a receiver utilizing a digital demodulator. The input signal (212) is split in the power splitter (201) into two equal but lower power version of the input signal. These signals are applied to two RF mixers (203, and 204). A local oscillator (211) generates a signal, at a frequency which when added to (or subtracted from) the input signal (212) yield a frequency which is in the center of the band of the bandpass filters (204). The output of the oscillator is passed through a Hybrid Coupler (202), which splits the oscillator's output into two signals with equal amplitudes but with a 90° phase relationship. The two signals generated by the hybrid coupler (202) are applied to the mixers (203, and 204) at their LO ports. As a result, the mixers (203, and 204) outputs are two signals at a frequency of the center of the bandpass filters, and with a 90° phase relationship between them. These signals pass through the bandpass filters, and are applied to the direct phase digitizer as “I” and “Q” (209, and 210 respectively). The digital processing is operating with a clock (not shown). On every clock cycle, the digitizer (206) generates a data output representing the phase of the input signal at the time of the clock transition. The digital demodulator (207) receives the data output from the digitizer (206) and extracts the modulating signal from the modulated input signal (212).

1. A demodulator for phase modulated (PM) signals comprising:
A direct phase sampler/digitizer;
A differencing circuit;
A “p” deep running averager;
A digital subtractor;
A phase to amplitude converter.

2. A demodulator as in claim 1, wherein the direct phase digitizer provides the instantaneous phase of the input signal, at the time of the clock transitions.

3. A demodulator as in claim 1, wherein a differencing circuit generates on every clock cycle the phase difference in the input signal over the clock period.

4. A demodulator as in claim 1, wherein a running averager generates a running average of phase differences over the last “p” consecutive phase differences.

5. A demodulator as in claim 1, wherein a subtractor subtracts the average phase difference generated by the averager from the instantaneous phase difference calculated by the differencing circuit and generates a digital data which indicates the instantaneous phase deviation.

6. A demodulator as in claim 1, wherein a phase to amplitude converter converts the instantaneous phase deviation generated by the subtractor into an amplitude directly proportional to the phase deviation.

7. A running averager as in claim 4, wherein “p” the depth of the averaging span determines the precision for the center frequency.

8. A phase to amplitude converter as in claim 6, wherein the conversion of phase information into a voltage output is obtained by a sine lookup table followed by a digital to analog converter.

9. A phase to amplitude converter as in claim 6, wherein the conversion of phase information into a voltage output is obtained by converting binary code presentation of the phase information into a Grey code followed by further processing using EXOR functions, bit drivers and a resistive network.

10. A demodulator for frequency modulated (FM) signals comprising:
A direct phase sampler/digitizer;
A differencing circuit;
A “p” deep running averager;
A second “q” deep running averager
A digital subtractor;
A phase to amplitude converter.

11. A demodulator as in claim 10, wherein the direct phase digitizer provides the instantaneous phase of the input signal, at the time of the clock transitions.

12. A demodulator as in claim 10, wherein a differencing circuit generates on every clock cycle the phase difference in the input signal over the clock period.

13. A demodulator as in claim 10, wherein a running averager generates a running average of phase differences over the last “p” consecutive phase differences.

14. A demodulator as in claim 10, wherein a second running averager generates a running average of phase differences over the last “q” consecutive phase differences.

15. A demodulator as in claim 10, wherein a subtractor subtracts the average phase difference generated by the averager from the instantaneous phase difference calculated by the differencing circuit and generates a digital data which indicates the instantaneous phase deviation.

16. A demodulator as in claim 10, wherein a phase to amplitude converter converts the instantaneous phase deviation generated by the subtractor into an amplitude directly proportional to the phase deviation.

17. A running averager as in claim 13, wherein “p” the depth of the averaging span determines the precision for the center frequency.

18. A second running averager as in claim 14, wherein “q” the depth of the averaging span of the second averager determines the bandwidth of the demodulated signal output.

19. A phase to amplitude converter as in claim 16, wherein the conversion of phase information into a voltage output is obtained by a sine lookup table followed by a digital to analog converter.

20. A phase to amplitude converter as in claim 6, wherein the conversion of phase information into a voltage output is obtained by converting binary code presentation of the phase information into a Grey code followed by further processing using EXOR functions, bit drivers and a resistive network.

21. An FM or PM receiver comprising:
A quadrature input signal generator;
A direct digital phase digitizer;
A digital demodulator.

22. A receiver as in claim 21, wherein the quadrature generation may be obtained by quadrature down conversion or by any type of quadrature power splitter.

23. A demodulator as in claim 21, wherein the direct phase digitizer provides the instantaneous phase of the input signal, at the time of the clock transitions.

24. A receiver as is claim 21, wherein the demodulator contains no tuned or resonant circuits and wherein the operation of the demodulator is controlled by a clock.

25. A converter to convert binary code presentation of the phase of a signal into a magnitude of voltage or current comprising:
EXOR Logic to convert the binary code into Grey code;
EXOR logic to generate specific driver code;
A resistive network to convert the drive code into a voltage or current.

26. A converter as in claim 25, wherein the conversion of binary code to Grey code is obtained using the formula Gₙ=Bₙ⊕Bₙ₊₁, and wherein Gₙ represents a Grey code bit n and Bₙ represents a binary code bit n.

27. A converter as in claim 25, wherein the drive code is obtained from the Grey code using the formula Dₖ|₀ⁿ=Gₖ⊕Gₖ₊₁⊕Gₖ₊₂⊕ . . . ⊕Gₙ, and wherein Dₖ represents a drive bit k.
